(19) United States
(12) Patent Application Publication
(10) Pub. No.: US 2010/0163923 A1
(43) Pub. Date: Jul. 1, 2010

(54) SEMICONDUCTOR DEVICE AND METHOD OF MANUFACTURING THE SAME

(76) Inventor: Yeo-Cho Yoon, Seongnam-si (KR)

Correspondence Address: SHERR & VAUGHN, PLLC, 620 HERNDON PARKWAY, SUITE 320, HERNDON, VA, 20170, US

(21) Appl. No.: 12/649,264

(22) Filed: Dec. 29, 2009

(30) Foreign Application Priority Data
Dec. 31, 2008 (KR) 10-2008-0137845

(51) Int. Cl. H01L 27/06; H01L 21/77

(52) U.S. Cl. 257/140; 438/135; 257/E21.598; 257/E27.015

(57) ABSTRACT

A semiconductor device may include a semiconductor substrate having a first deep N well and/or a second deep N well, a first isolation layer over a first deep N well, and/or a first P well over a first deep N well. A semiconductor device may include an NMOS transistor over a first P well and/or a PMOS transistor over a first deep N well at an opposite side of a first isolation layer. A semiconductor device may include a second P well over a second deep N well, a second isolation layer interposed between a second deep N well and a second P well, and/or an emitter including first type impurities over a second deep N well. A semiconductor device may include a third isolation layer over a second P well, a collector including first type impurities over a second P well, and/or a base formed over a second P well and/or having a bottom surface to make contact with an emitter.

The present application claims priority under 35 U.S.C. 119 to Korean Patent Application No. 10-2008-0137845 (filed on Dec. 31, 2008) which is hereby incorporated by reference in its entirety.

### BACKGROUND

Embodiments relate to a semiconductor device and methods thereof. Some embodiments relate to a semiconductor device and a method of manufacturing the same, in which noise and/or frequency characteristics may be maximized.

When comparing a Metal-Oxide Semiconductor Field Effect Transistor (MOSFET) to a Bipolar Junction Transistor (BJT), a BJT may have maximized current performance and/or relatively faster operating speed. Accordingly, use of a BJT in a specific part of an individual product may be increased relative to use of a MOSFET.

An analog complementary metal oxide semiconductor (CMOS) device may include a maximized frequency response characteristic. However, a CMOS semiconductor device may be inferior relative to a compound semiconductor and/or a bipolar device in terms of a power gain and/or a noise characteristic under a relatively low frequency. As an integration degree of a device may become relatively increased, noise may relatively increase in proportion to a trap density of a gate oxide layer that may be a relatively important factor of a noise characteristic, such that a noise characteristic may not be improved.

Accordingly, there is a need of a semiconductor device and methods thereof which may be capable of maximizing a frequency characteristic and/or a noise characteristic.

### SUMMARY

Embodiments relate to a semiconductor device and methods thereof. Some embodiments relate to a semiconductor device and a method of manufacturing the same. According to embodiments, noise characteristics may be maximized by relatively reducing resistance of a base by a bipolar transistor including a bottom emitter structure in a complementary metal oxide semiconductor (CMOS) transistor process. In embodiments, a semiconductor device and a method of manufacturing the same may be capable of realizing a relatively high-integrated device, for example by forming a CMOS transistor and a bipolar transistor on and/or over a single substrate.

According to embodiments, a semiconductor device may include a semiconductor substrate having a first deep N well which may define a CMOS region and/or a second deep N well which may define a bipolar region. In embodiments, a semiconductor device may include a first isolation layer formed on and/or over a first deep N well. In embodiments, a semiconductor device may include a first P well formed on and/or over a first deep N well at one side of a first isolation layer. In embodiments, a semiconductor device may include an NMOS transistor formed on and/or over a first P well. In embodiments, a semiconductor device may include a PMOS transistor formed on and/or over a first deep N well at an opposite side of a first isolation layer.

According to embodiments, a semiconductor device may include a second P well formed on and/or over a second deep N well which may expose a portion of a second deep N well. In embodiments, a semiconductor device may include a second isolation layer interposed between a second deep N well and a second P well which may define an emitter region. In embodiments, a semiconductor device may include an emitter including first type impurities on and/or over a second deep N well. In embodiments, a semiconductor device may include a third isolation layer which may define a base region and/or a collector region on and/or over a second P well. In embodiments, a semiconductor device may include a collector having first type impurities on and/or over a second P well interposed between second and third isolation layers, and/or a base formed on and/or over a second P well at one side of a third isolation layer, including a bottom surface having second type impurities which may contact an emitter.

According to embodiments, a method of manufacturing a semiconductor device may include forming first and/or second deep N wells on and/or over a semiconductor substrate which may define CMOS and/or bipolar regions, respectively. In embodiments, a method of manufacturing a semiconductor device may include forming a first isolation layer on and/or over a first deep N well which may define NMOS and/or PMOS regions. In embodiments, a method of manufacturing a semiconductor device may include forming second and/or third isolation layers on and/or over a second deep N well which may define emitter, collector, and/or base regions.

According to embodiments, a method of manufacturing a semiconductor device may include forming a first P well on and/or over a first deep N well at one side of a first isolation layer. In embodiments, a method of manufacturing a semiconductor device may include forming a second P well on and/or over a second deep N well at one side of a second isolation layer. In embodiments, a method of manufacturing a semiconductor device may include forming a first gate on and/or over a first P well and/or forming a second gate on and/or over a first deep N well.

According to embodiments, a method of manufacturing a semiconductor device may include forming a first source/drain by implanting first type impurities on and/or over a first P well. In embodiments, a method of manufacturing a semiconductor device may include forming an emitter and/or a collector by implanting first type impurities on and/or over an emitter region and/or a collector region. In embodiments, a method of manufacturing a semiconductor device may include forming a second source/drain by implanting second type impurities on and/or over a first deep N well. In embodiments, a method of manufacturing a semiconductor device may include forming a base by implanting second type impurities on and/or over a base region.

### DRAWINGS

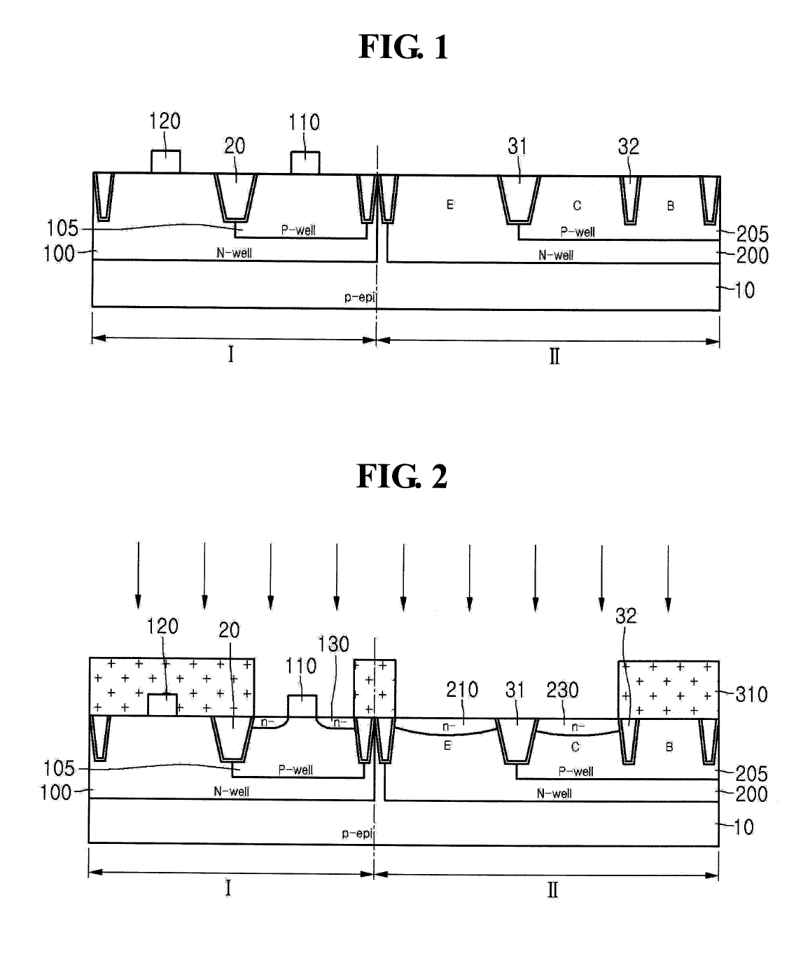

Example FIG. 1 to FIG. 8 are sectional views illustrating a manufacturing process of a semiconductor device in accordance with embodiments.

### DESCRIPTION

Embodiments relate to a semiconductor device and methods thereof. Some embodiments relate to a semiconductor device and a method of manufacturing the same Referring to example FIG. 8, a sectional view illustrates a semiconductor device in accordance with embodiments. According to embodiments, a semiconductor device may include semiconductor substrate 10 having first deep N well 100 which may define CMOS region I and/or second deep N well 200 which may define bipolar region II. In embodiments, a semiconductor device may include first isolation layer 20 formed on and/or over first deep N well 100, first P well 105 formed on and/or over first deep N well 100 at one side of first isolation layer 20, an NMOS transistor (NMOS TR) formed on and/or over first P well 105, and/or a PMOS transistor (PMOS TR) formed on and/or over first deep N well 100 at the other side of first isolation layer 20.

According to embodiments, a semiconductor device may include second P well 205 formed on and/or over second deep N well 200 which may expose a portion of second deep N well 200. In embodiments, a semiconductor device may include second isolation layer 31 formed between second deep N well 200 and second P well 205 which may define an emitter region. In embodiments, a semiconductor device may include emitter E including first type impurities on and/or over second deep N well 200. In embodiments, a semiconductor device may include third isolation layer 32 which may define base and/or collector regions on and/or over second P well 205. In embodiments, a semiconductor device may include collector C including first type impurities on and/or over second P well 205 between second and third isolation layers 32. In embodiments, a semiconductor device may include base B formed on and/or over second P well 205 at one side of third isolation layer 32, which may include a bottom surface having second type impurities to make contact with emitter E.

According to embodiments, emitter E, base B, and/or collector C may include N type impurities, P type impurities, and/or N type impurities, and/or may form an NPN bipolar TR. In embodiments, emitter E may be formed on and/or over second deep N well 200. In embodiments, base B may be formed on and/or over second P well 205. In embodiments, collector C may be formed on and/or over second P well 205, such that emitter E may have a bottom emitter structure. In embodiments, collector C may be formed on and/or over second P well 205 having base B, such that a contact area between base B and collector C may be narrowed, which may minimize resistance. In embodiments, an electrical characteristic of a device may be maximized.

According to embodiments, interlayer dielectric layer 40 may be formed on and/or over NMOS TR, PMOS TR, and/or bipolar TR. In embodiments, first and/or second contact plugs 51, 52, respectively, may be formed on and/or over a source/drain of NMOS TR and/or PMOS TR while passing through interlayer dielectric layer 40. In embodiments, emitter electrode 53, collector electrode 54, and/or base electrode 55 may be formed on and/or over emitter E, collector C, and/or base B of a bipolar TR. In embodiments, bipolar TR having a bottom emitter structure may be adapted to a CMOS device, such that a current gain and/or a breakdown voltage characteristic may be relatively improved. In embodiments, frequency and/or noise characteristics may be maximized.

Embodiments relate to a method of manufacturing a semiconductor device. Referring to example FIG. 1 to FIG. 8, a method of manufacturing a semiconductor device in accordance with embodiments is illustrated. According to embodiments, a vertical type NPN BJT device may be realized through a deep N-well CMOS process. Referring to FIG. 1, first N-well 100 and/or second N-well 200 may be formed on and/or over first region I and/or second region II of semiconductor substrate 10. In embodiments, first region I may include a region in which CMOS TR may be formed, and/or second region II may be a region in which NPN bipolar TR may be formed. In embodiments, semiconductor substrate 10 may include a single crystalline and/or poly-crystalline silicon substrate, and/or may be doped with P type impurities and/or N type impurities. In embodiments, semiconductor substrate 10 may include a P type (P++) substrate. In embodiments, a low concentration P type epitaxial layer (p-epi) may be formed on and/or over semiconductor substrate 10 through an epitaxial process.

According to embodiments, first and/or second deep wells 100 and/or 200 may be formed through a heat treatment process after ions have been relatively deeply implanted on and/or over first region I and/or second region II of semiconductor substrate 10. In embodiments, first to third isolation layers 20, 31, and/or 32 may formed on and/or over first region I and/or second region II which may define an active region. In embodiments, first to third isolation layers 20 to 32 may be formed by gap-filling an oxide layer on and/or over a trench after forming a trench through an STI process. In embodiments, a barrier layer including P type impurities may be formed around first to third isolation layers 20 to 32.

According to embodiments, first isolation layer 20 of first region I may define an NMOS region and/or a PMOS region of CMOS TR. In embodiments, an NMOS region may be formed at one side of first isolation layer 20 and/or a PMOS region may be formed at the other side of first isolation layer 20. In embodiments, second and/or third isolation layers 31 and/or 32 of second region II may define an emitter region, a collector region, and/or a base region of bipolar TR. In embodiments, first P-well 105 may be formed on and/or over first deep N well 100 which may form an NMOS region. In embodiments, second P well 205 may be formed on and/or over second deep N well 200 which may from collector C and/or base B.

According to embodiments, first P well 105 may be selectively formed on and/or over first deep N well 100 such that an NMOS region and/or a PMOS region may be formed. In embodiments, second P well 205 may be selectively formed on and/or over second deep N well 200 such that emitter, collector, and/or base regions may be formed. In embodiments, second deep N well 200 and/or second P well 205 may be divided into each other by second isolation layer 31. In embodiments, second P well 205 may be divided by third isolation layer 32. In embodiments, an emitter region may be formed on and/or over second deep N well 200. In embodiments, collector and/or base regions may be formed on and/or over second P well 205.

According to embodiments, first and/or second P wells 105 and/or 205 may be formed by implanting P type impurities after forming a photoresist pattern on and/or over semiconductor substrate 10 to selectively expose an NMOS region and/or collector and/or base regions. In embodiments, first P well 105 may be formed on and/or over first deep N well 100. In embodiments, second P well 205 may be formed on and/or over second deep N well 200. In embodiments, first gate 110 may be formed on and/or over the first P well 105, and/or second gate 120 may be formed on and/or over first deep N well 100. In embodiments, first and/or second gates 110, 120 may be selectively formed on and/or over first P well 105 and/or first deep N well 100 by selectively pattering a gate oxide layer and/or a gate conductive layer after a gate oxide layer and/or a gate conductive layer may be deposited on and/or over semiconductor substrate 10.

Referring to FIG. 2, first photoresist pattern 310 may be formed on and/or over semiconductor substrate 10. According to embodiments, first photoresist pattern 310 may expose first P well 105, and/or may expose an emitter region of second deep N well 200 and/or a collector region of second P well 205. In embodiments, first photoresist pattern 310 may expose an NMOS region at one side of first isolation layer 20. In embodiments, first photoresist pattern 310 may expose second deep N well 200 at the other side of second isolation layer 31, and/or may selectively expose second P well 205 between second and third isolation layers 31, 32.

According to embodiments, first LDD regions 130 may be formed at relatively shallow regions of first P well 105 at both sides of first gate 110. In embodiments, first type shallow doped layers 210, 230 may be formed at a relatively shallow portion of emitter and/or collector regions on and/or over second deep N well 200. In embodiments, first LDD regions 130 and/or first type shallow doped layers 210, 230 may be formed with lightly doped N type impurities (n−). In embodiments, first LDD regions 130 and/or first type shallow doped layers 210, 230 may be formed by implanting N type impurities on and/or over first P well 105, emitter and/or collector regions using photoresist pattern 310 as an ion implantation mask. In embodiments, N type impurities may include phosphorus ions (31P+) belonging to a V-group. In embodiments, first photoresist pattern 310 may be substantially removed.

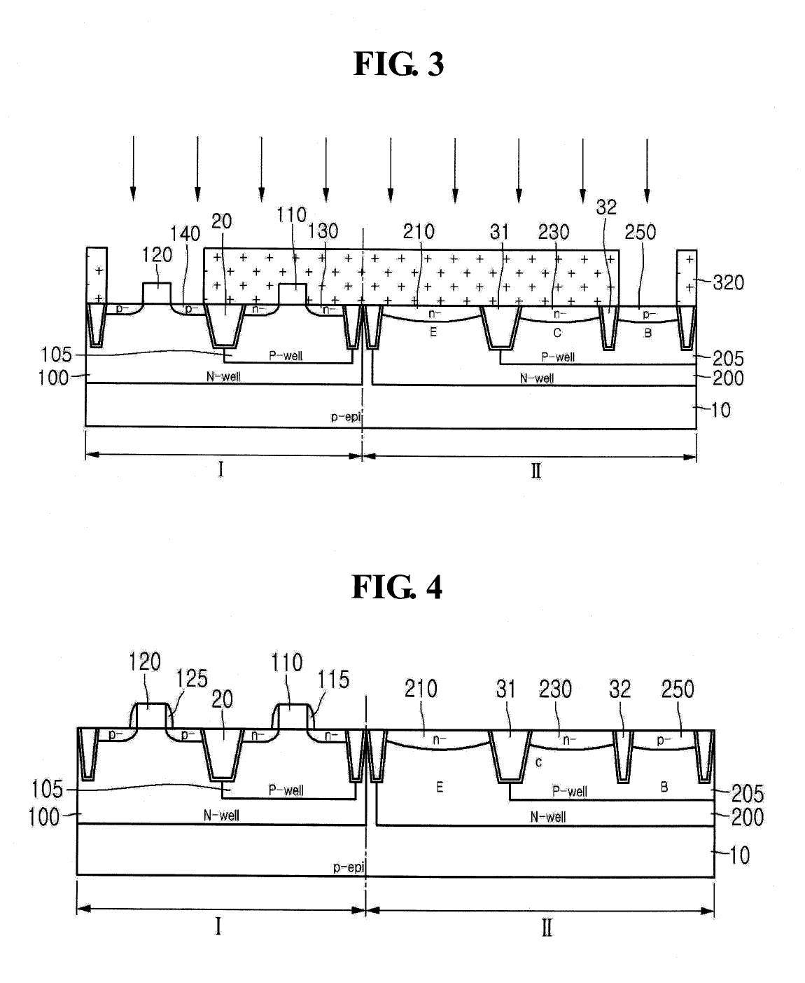

Referring to FIG. 3, second photoresist pattern 320 may be formed on and/or over semiconductor substrate 10. According to embodiments, second photoresist pattern 320 may expose first deep N well 100, and/or may selectively expose a base region of second P well 205. In embodiments, second photoresist pattern 32 may expose a PMOS region at the other side of first isolation layer 20, and/or may expose second P well 205 at the other side of third isolation layer 32. In embodiments, second LDD regions 140 may be formed at relatively shallow regions of first deep N well 100 at both sides of second gate 120. In embodiments, second type shallow doped layer 250 may be formed at a relatively shallow region of base B of second P well 205. In embodiments, second LDD regions 140 and second type shallow doped layer 250 may be formed by implanting P type impurities on and/or over first deep N well 100 and/or a base region using second photoresist pattern 320 as an ion implantation mask. In embodiments, P type impurities may include boron ions (B+) belonging to a III-group. In embodiments, second photoresist pattern 320 may be substantially removed.

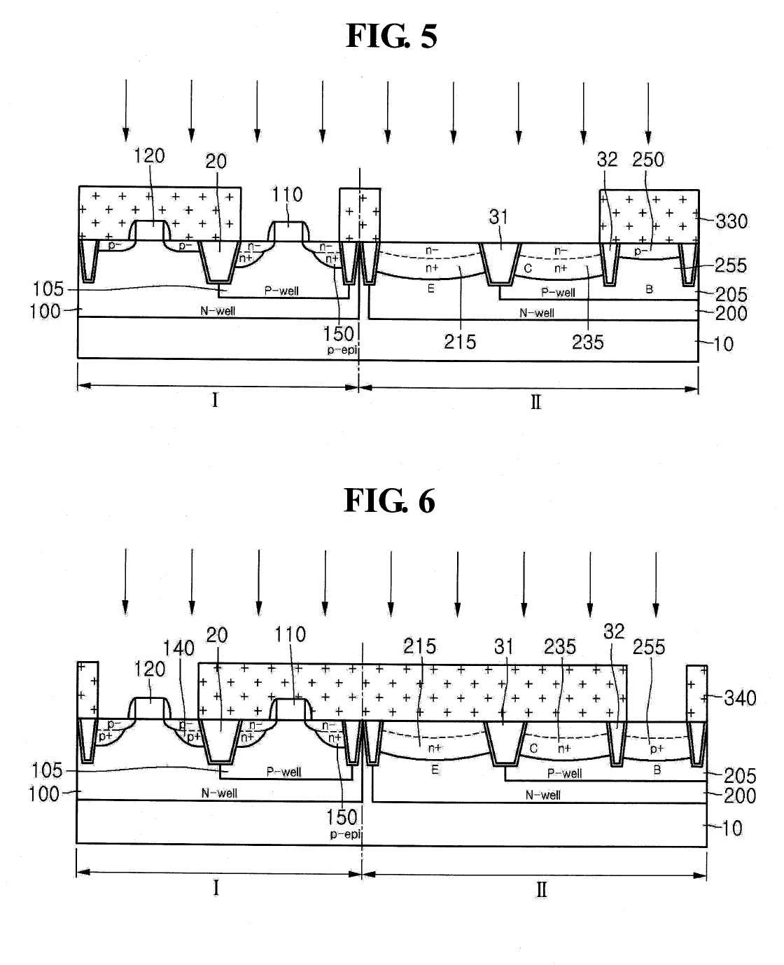

Referring to FIG. 4, spacers 115 and/or 125 may be formed at sidewalls of first and/or second gates 110 and/or 120. According to embodiments, spacers 115 and/or 125 may be formed by etching an entire surface of semiconductor substrate 10 after forming an insulating layer on and/or over semiconductor substrate 10. Referring to FIG. 5, third photoresist pattern 330 may be formed on and/or over semiconductor substrate 10. In embodiments, third photoresist pattern 330 may selectively expose first P well 105, an emitter region on and/or over second deep N well 200, and/or a collector region of second P well 205. In embodiments, third photoresist pattern 330 may be formed using substantially the same mask as that of first photoresist pattern 310.

According to embodiments, first source/drain 150 may be formed at a relatively deep region of first P well 105, such that first source/drain 150 may be aligned with spacer 115 of first gate 110. In embodiments, first type deep doped layers 215 and/or 235 may be formed such that first type deep doped layers 215 and/or 235 make contacts with first type shallow doped layers 210 and/or 230 of emitter and/or collector regions of second deep N well 200. In embodiments, first source/drain 150 and/or first type deep doped layers 215 and/or 235 may include high-concentration n type impurities. In embodiments, n type impurities may include arsenic ions (75As+) belonging to a V group. In embodiments, emitter E may be formed by first type shallow doped layer 210 and/or first type deep doped layer 215 of an emitter region. In embodiments, collector C may be formed by first type shallow doped layer 230 and/or first type deep doped layer 235 of collector region. In embodiments, emitter E and/or collector C may include N type impurities. In embodiments, emitter E may be separated from collector C by second P well 205. In embodiments, third photoresist pattern 330 may be substantially removed.

Referring to FIG. 6, fourth photoresist pattern 340 may be formed on and/or over semiconductor substrate 10. According to embodiments, fourth photoresist pattern 340 may expose first deep N well 100, and/or may selectively expose a base region of second P 205 well. In embodiments, fourth photoresist pattern 340 may be formed using substantially the same mask as that of second photoresist pattern 320. In embodiments, second source/drain 140 may be formed at a relatively deep region of first deep N well 100 such that second source/drain 140 may be aligned with spacer 125 of second gate 120. In embodiments, second type deep doped layer 255 may be formed such that second type deep doped layer 255 may make contact with second type shallow doped layer 250 of second P well 205.

According to embodiments, source/drain 140 and/or second deep doped layer 255 may be formed by implanting P type impurities on and/or over first deep N well 100 and/or a base region using fourth photoresist pattern 340 as an ion implantation mask. In embodiments, P type impurities may include boron ions (49 BF+) belonging to a III group. In embodiments, base B may be formed on and/or over abase region by second type shallow doped layer 250 and/or second type deep doped layer 255. In embodiments, base B may include P type impurities substantially the same as those of second P well 205. In embodiments, base B may be interposed between collector C and emitter E, such that collector C may be separated from emitter E. According to embodiments, emitter E, collector C, and/or base B may form an NPN bipolar structure. In embodiments, emitter E may be formed on and/or over second deep N well 200.

According to embodiments, bipolar TR may include a bottom emitter structure. In embodiments, a current gain and/or a breakdown voltage characteristic may be maximized. In embodiments, low-frequency noise in a MOS structure may be overcome. In embodiments, fourth photoresist pattern 340 may be substantially removed. In embodiments, CMOS TR and/or bipolar TR may be formed on and/or over one substrate, such that a device may be integrated. In embodiments, first and/or second LDD regions 130 and/or 140, and/or first and/or second source/drain 150 and/or 160 of CMOS TR may be formed, and/or emitter E, collector C, and/or base B of bipolar TR may be formed at substantially the same time. In embodiments, an additional mask process may be omitted, such that productivity may be maximized.

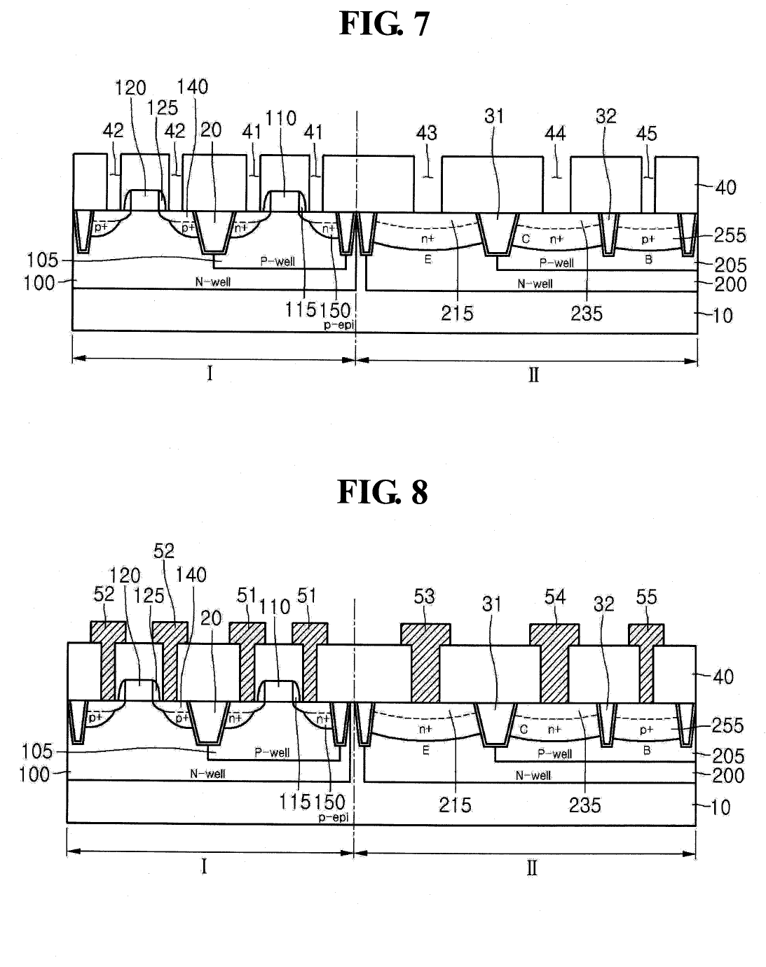

Referring to FIG. 7, interlayer dielectric layer 40 may be formed on and/or over semiconductor substrate 10 including CMOS TR and/or bipolar TR. According to embodiments, interlayer dielectric layer 40 may include an oxide layer and/or a nitride layer. In embodiments, first to fifth contact holes 41 to 45 passing through interlayer dielectric layer 40 may be formed. In embodiments, first contact hole 41 may expose first source/drain 150. In embodiments, second contact hole 42 may expose second source/drain 160. In embodiments, third contact hole 43 may expose a surface of emitter E. In embodiments, fourth contact hole 44 may expose a surface of collector C. In embodiments, fifth contact hole 45 may expose a surface of base B.

Referring to FIG. 8, first to fifth contact holes 41 to 45 may be gap-filled with a metal layer. for example including tungsten (W), thereby forming first and/or second contact plugs 51 and/or 52, emitter electrode 53, collector electrode 54, and/or base electrode 55. According to embodiments, NPN bipolar TR may be formed on and/or over a semiconductor substrate having CMOS TR, such that devices may be integrated. In embodiments, frequency and/or noise characteristic may be maximized in a CMOS TR. In embodiments, an NMOS device of a CMOS TR may be formed, and/or an emitter and/or collector of a bipolar TR may be formed at substantially the same time. In embodiments, a PMOS device of CMOS TR may be formed, and/or a base of bipolar TR may be formed at substantially the same time. In embodiments, an additional ion implantation mask used to form a bipolar TR may be omitted. In embodiments, a manufacturing process may be simplified, and/or productivity may be maximized. In embodiments, a bipolar TR having a maximized flicker noise characteristic may be used and/or a maximized phase noise characteristic may be obtained. In embodiments, a semiconductor device may be applicable to a device such as a voltage controlled oscillator (VCO) circuit.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

1-20. (canceled)

22. An apparatus comprising:
a semiconductor substrate including a first deep N well defining a CMOS region and a second deep N well defining a bipolar region;
a first isolation layer formed over said first deep N well;
a first P well formed over said first deep N well at one side of said first isolation layer;
an NMOS transistor formed over said first P well and a PMOS transistor formed over said first deep N well at an opposite side of said first isolation layer;
a second P well formed over said second deep N well exposing a portion of said second deep N well;
a second isolation layer interposed between said second deep N well and said second P well defining an emitter region;
an emitter including first type impurities over said second deep N well;
a third isolation layer defining a base region and a collector region over said second P well;
a collector including first type impurities over said second P well interposed between said second and third isolation layers; and
a base formed over said second P well at one side of said third isolation layer, comprising a bottom surface including second type impurities to make contact with the emitter.

23. The apparatus of claim 22, wherein the emitter comprises N type impurities, the base comprises P type impurities, and the collector comprises N type impurities, forming an NPN bipolar transistor.

24. The apparatus of claim 22, wherein the emitter is over said second deep N well, the base is over said second P well, and the collector is over said second P well, the emitter comprises a bottom emitter structure.

25. The apparatus of claim 22, comprising a low concentration P type epitaxial layer over said semiconductor substrate.

26. The apparatus of claim 22, comprising at least one of:
a first gate over said first P well; and
a second gate over said first deep N well.

27. The apparatus of claim 26, comprising at least one spacer formed at a sidewall of said at least one of said first gate and second gate.

28. The apparatus of claim 22, comprising at least one of a first and a second contact plug over at least one of a source/drain of said NMOS transistor and said PMOS transistor.

29. The apparatus of claim 22, comprising an emitter electrode, a collector electrode and a base electrode.

30. The apparatus of claim 22, wherein said semiconductor substrate comprises a P type (P++) substrate.

31. A method comprising:
forming first and second deep N wells over a semiconductor substrate defining a CMOS and a bipolar region;
forming a first isolation layer over said first deep N well defining NMOS and PMOS regions;
forming second and third isolation layers over said second deep N well defining emitter, collector, and base regions;
forming a first P well over said first deep N well at one side of said first isolation layer;
forming a second P well over said second deep N well at one side of said second isolation layer;
forming a first gate over said first P well and forming a second gate over said first deep N well;
forming a first source/drain by implanting first type impurities over said first P well, and forming an emitter and a collector by implanting said first type impurities over said emitter region and the collector region; and
forming a second source/drain by implanting second type impurities over said first deep N well, and forming a base by implanting said second type impurities over said base region.

32. The method claim 31, wherein the emitter and the collector comprise N type impurities, and the base comprises P type impurities, forming an NPN bipolar transistor.

33. The method of claim 31, comprising:
forming a first photoresist pattern over said semiconductor substrate such that said first P well, said emitter region, and said collector region are selectively exposed;
forming LDD regions over said first P well corresponding to both sides of said first gate, and forming first type shallow doped regions at a portion of said second deep N well and said second P well corresponding to said emitter region and said collector region using said first photoresist pattern as an ion implantation mask, after forming said first and second gates.

34. The method of claim 33, wherein forming said first source/drain of said first P well and forming the emitter and the collector comprises:
forming a third photoresist pattern using a mask identical to a mask of said first photoresist pattern; and
forming said first source/drain below said LDD regions and said first type deep doped layer below said first type shallow doped layer using said third photoresist pattern as an ion implantation mask.

35. The method of claim 31, comprising:
forming a second photoresist pattern over said semiconductor substrate such that said first deep N well and said base region are selectively exposed;
forming LDD regions over said first deep N well corresponding to both sides of said second gate, and forming a second type shallow doped region at a portion of said second P well corresponding to said base region, after forming the first and second gates.

36. The method of claim 35, where forming said second source/drain of said first deep N well and forming the base comprises:
forming a fourth photoresist pattern using a mask identical to a mask of said second photoresist pattern; and
forming said second source/drain below said LDD regions and said second type deep doped layer below said second type shallow doped layer using said fourth photoresist pattern as an ion implantation mask.

37. The method of claim 31, comprising:
forming an interlayer dielectric layer over said semiconductor substrate; and
forming emitter, collector, and base electrodes, which are respectively connected to the emitter, the collector, and the base through said interlayer dielectric layer, after forming the base over said base region.

38. The method of claim 37, wherein said interlayer dielectric layer comprises at least one of an oxide layer and a nitride layer

39. The method of claim 31, comprising forming a low concentration P type epitaxial layer over said semiconductor substrate formed comprising an epitaxial process.

40. The method of claim 31, comprising forming at least one spacer at a sidewall of said at least one of said first gate and second gate.

41. The method of claim 31, comprising at least one of a first and a second contact plug over at least one source/drain of said NMOS transistor and said PMOS transistor.
